(19) United States
(12) Patent Application Publication
(10) Pub. No.: US 2006/0294441 A1
(43) Pub. Date: Dec. 28, 2006

(54) Logic analyzer data retrieving circuit and its retrieving method

(75) Inventors: Chiu Hao Cheng, Yuan-Li, Miaoli Hsien (TW); Ming-Gwo Cheng, Taichung Hsien (TW); Chun-Feng Tzu, Miaoli Hsien (TW); Hung-Yeh Chung, Taipei Hsien (TW)

Correspondence Address: BACON & THOMAS, PLLC, 625 SLATERS LANE, FOURTH FLOOR, ALEXANDRIA, VA, 22314, US

(73) Assignee: Zeroplus Technology Co., Ltd., Chungho City, Taipei Hsien (TW)

(21) Appl. No.: 10/552,891

(22) PCT Filed: Apr. 8, 2003
(86) PCT No.: PCT/US03/09201

§ 371 Date: Oct. 11, 2005

(51) Int. Cl. G11C 29/00

(52) U.S. Cl. 714/718

(57) ABSTRACT

A logic analyzer data retrieving method used in a logic analyzer formed of a control unit (11), a memory unit (12), and a data retrieving circuit (13), is disclosed to include the step of driving the data retrieving circuit of the logic analyzer to receive a time delay default value and to store in a buffer in a time delay circuit, and the step of triggering the preset of a first counter and transferring the default value from the buffer to the first counter to drive the first counter to start counting when a clock qualifier signal entered so as to obtain a complete clock enable signal when the first counter counted up to the default value and the output of the clock enable became low.

### BACKGROUND OF THE INVENTION

1. Field of the Invention

The present invention relates to a logic analyzer data retrieving circuit and its retrieving method and, more particularly, to such a logic analyzer data retrieving circuit, which is capable of retrieving a complete clock enable signal and, which enables the user to know the time interval between two clock enable signals.

2. Description of the Related Art

Nowadays, most electronic apparatus are digitalized. Conventional oscilloscopes are not suitable for examining sophisticated electronic apparatus for being not capable of measuring signals having more than 8˜16 channels. An ICE (in circuit emulator) solves many digitalizing problems. However, a software development-oriented ICE cannot manage a real time sequencing problem. Further, an ICE is adapted to fit a particular microcomputer system. Due to the aforesaid reasons, most engineers use a logic analyzer as one of the requisite measuring instruments. A logic analyzer can indicate the desired data by a format, so that the user can conveniently show the process of the action of a digital circuit on the screen of the logic analyzer.

Regular logic analyzers include two analyzing modes, one is the asynchronous mode or the so-called “time sequence analysis”, and the other is the synchronous mode or the so-called “status analysis”. The on-screen waveform display method of the asynchronous mode is similar to an oscilloscope. According to the synchronous mode, the sampled clock signal is provided by the test sample. As indicated, the time sequence analysis mode and the status analysis mode use different sampling clocks. Under the status analysis mode, we use the signal from one particular channel as sampling clock (normally, the clock of the test sample). The sampling clock can be a combination of signals from different channels. Further, the use may assemble a clock signal in the circuit to be tested, and then send the clock signal to the logic analyzer for use as a sampling clock. Under the time sequence analysis mode, there are two different sampling methods available. The first sampling method is “continuous storing mode”, in which the logic analyzer has a constant sampling clock that is continuously sampling and continuously storing in memory. The second sampling method is “state transition sampling mode”, which enables use to effectively utilize limited memory. When sampling, it does not store data. However, it stores the transited state and the time between the last two transitions each time a state transition is detected. This method does not save much memory space when state transition is frequent. However, it saves much memory space and improves the resolution if the signal is composed of a number of bursts and the time in which the state remains unchanged is long.

Another useful function of a logic analyzer is the qualifier. There are two different qualifiers, namely, the trigger qualifier and the clock qualifier. Trigger qualifier is subject to a particular condition, i.e., it occurs only when the condition of letter recognition simultaneously occurred. Trigger qualifier enables the user to add an additional condition to trigger. Clock qualifier is used to limit sampling clock. By means of clock qualifier, the user can select data to be stored in the memory, preventing occupation of memory space by unnecessary data. This method enables the memory space of the memory to be used effectively. FIGS. 1˜3 show the arrangement of a logic data analyzer, and the related data retrieving circuit and waveform according to the prior art. The logic analyzer A10 comprises control circuit A11 and a memory (for example, SRAM) A12. When the control circuit A11 received examination data from the test sample A30, it stores received data in the memory A12. When the memory space of the memory A12 used up (fully occupied), the control circuit A11 transmit storage data from the memory A12 to an external computer system A40 through a communication interface A20, enabling the data to be displayed on the display screen of the computer system A40 for check visually. According to this design, inputted clock and clock qualifier are processed through an AND gate into an output of qualified clock. The logic analyzer uses this qualified clock as sampling clock to catch the desired data. However, because the AND gate is a logic operator of binary system, the result will be “Hi” when the two clock enables are “Hi”. If the two clock enables are not all “Hi”, the result will be “Lo”. At this, as shown in FIG. 3, the received amount of data is reduced, however the important ready signal is still not obtainable. Due to this reason, the waveform data is incomplete when the retrieval qualified, resulting in the following drawbacks:
1. The user cannot see the complete waveform after qualification.
2. The user cannot know the time difference between two sampled clocks.

Therefore, it is desirable to provide a logic analyzer data retrieving circuit that eliminates the aforesaid drawbacks.

### SUMMARY OF THE INVENTION

The present invention has been accomplished under the circumstances in view. It is therefore the main object of the present invention to provide a logic analyzer data retrieving circuit and its retrieving method, which eliminates the aforesaid drawbacks.

According to one aspect of the present invention, the logic analyzer data retrieving method is used in a logic analyzer comprised of a control unit, a memory unit, and a data retrieving circuit. The data retrieving circuit obtains a qualified clock when received a clock signal and a clock qualifier signal, for enabling the control unit to catch test data from a test sample been connected thereto subject to the qualified clock, and to store caught test data in the memory unit and then to transfer test data from the memory unit to the display screen of an external computer system for examination. The logic analyzer data retrieving method comprises the step of driving the data retrieving circuit to receive a time delay default value and to store the time delay default value in a buffer in a time delay circuit, and the step of triggering the preset of a first counter and transferring the default value from the buffer to the first counter to drive the first counter to start counting when a clock qualifier signal entered, so as to obtain a complete clock enable signal when the first counter counted up to the default value and the output of the clock enable became low. According to another aspect of the present invention, the logic analyzer data retrieving method further comprising the step of triggering the reset of a second counter of the control circuit to cause the second counter to start counting till appearance of a next clock enable signal when a complete clock enable ended, and the step of storing the value of the second counter in the memory unit when the second counter stopped the counting and then displaying the value on a display screen.

### BRIEF DESCRIPTION OF THE DRAWINGS

FIG. 1 is a circuit block diagram according to the prior art.

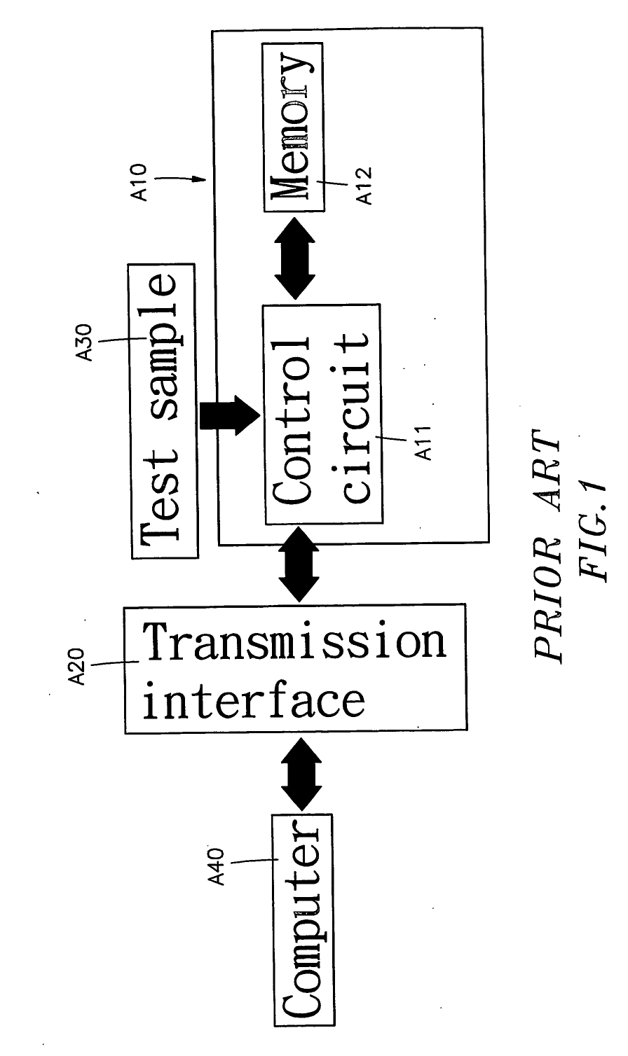

FIG. 2 is a schematic drawing showing a clock signal and a clock qualifier signal processed into a qualified clock signal according to the prior art.

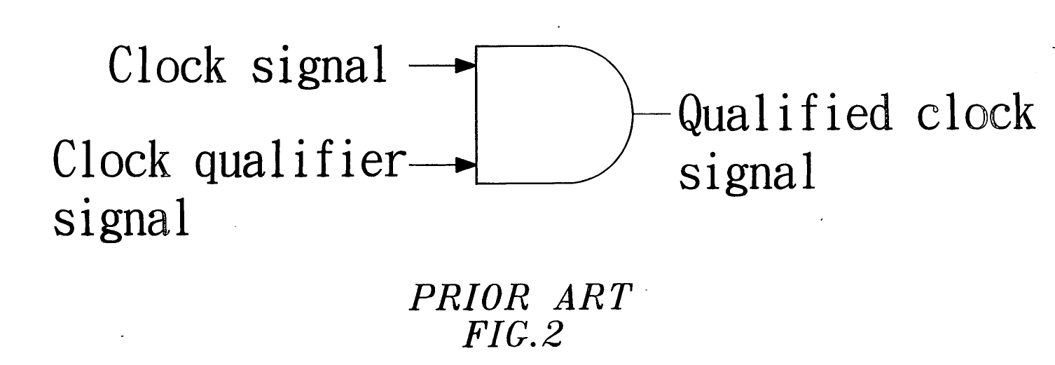

FIG. 3 is a schematic drawing showing a waveform obtained according to the prior art.

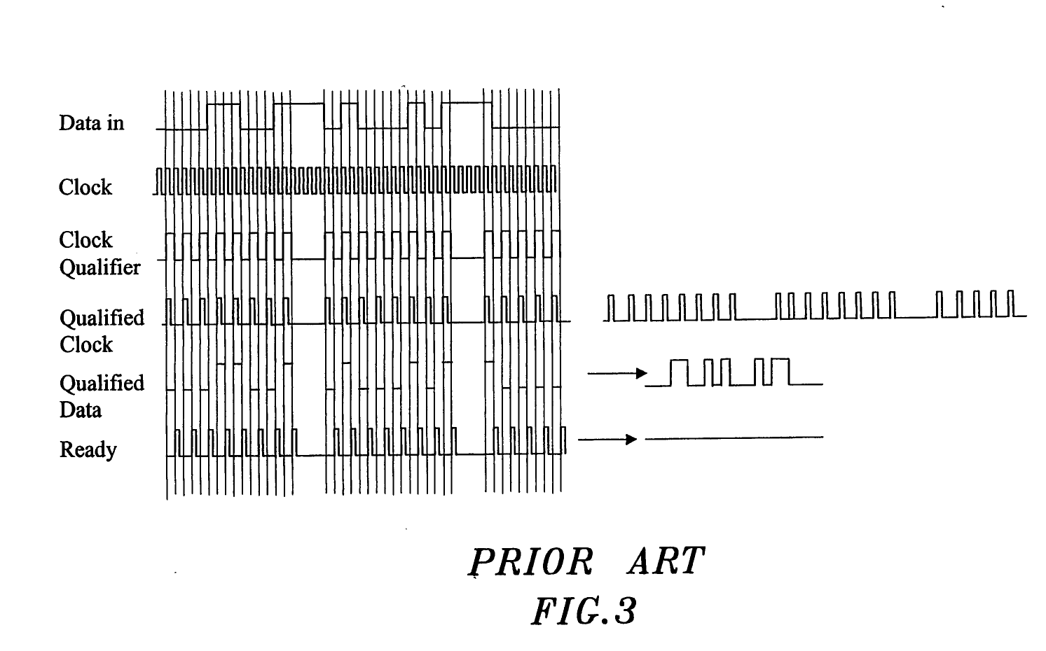

FIG. 4 is a circuit block diagram of a logic analyzer according to the present invention.

FIG. 5 is a circuit block diagram of the data retrieving circuit according to the present invention.

FIG. 6 is a schematic drawing showing a waveform obtained according to the present invention.

FIG. 7 is a circuit block diagram of an alternate form of the logic analyzer according to the present invention.

### DETAILED DESCRIPTION OF THE PREFERRED EMBODIMENT

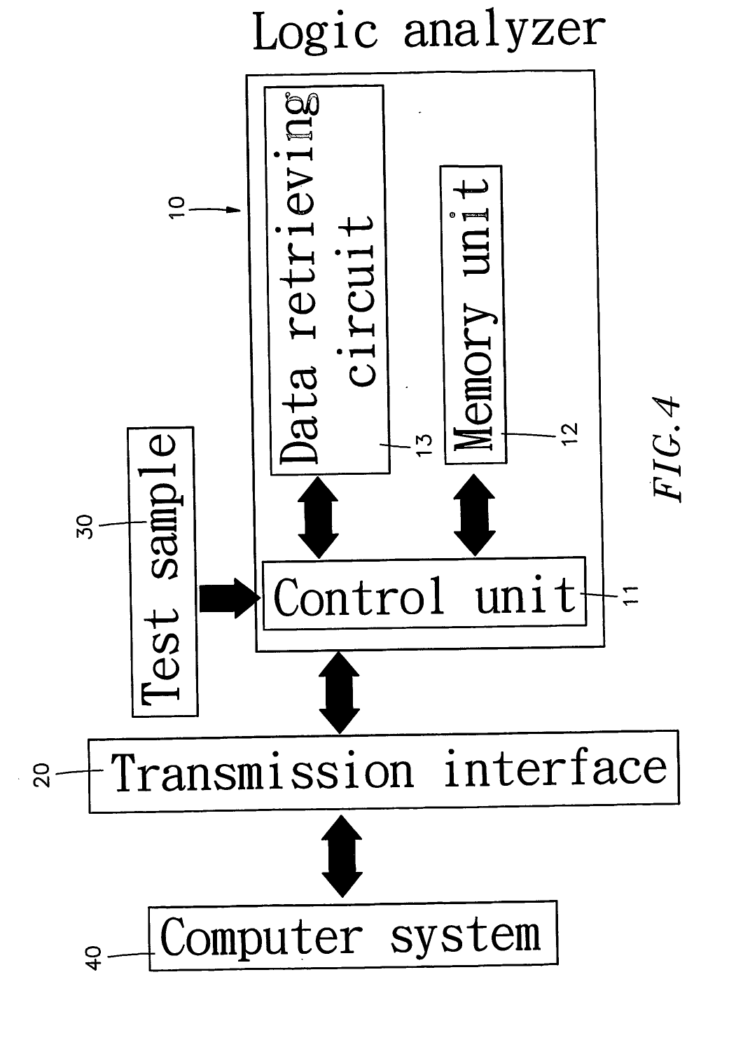

Referring to FIG. 4, a logic analyzer 10 is shown comprising a control unit 11, a memory unit (for example, SRAM) 12, and a data retrieving circuit 13. When the data retrieving circuit 13 received a clock signal and a clock qualifier signal, it outputs a qualified clock to the control unit 11. Upon receipt of the qualified clock, the control unit 11 uses the qualified clock as a sampling clock to catch test data from the test sample 30, and then to store caught test data in the memory unit 12, and then to transfer storage test data from the memory unit 12 to an external computer system 40 through a transmission interface 20 when the memory space of the memory unit 12 used up (fully occupied), enabling the test data to be displayed on the display screen of the computer system 40 for examination.

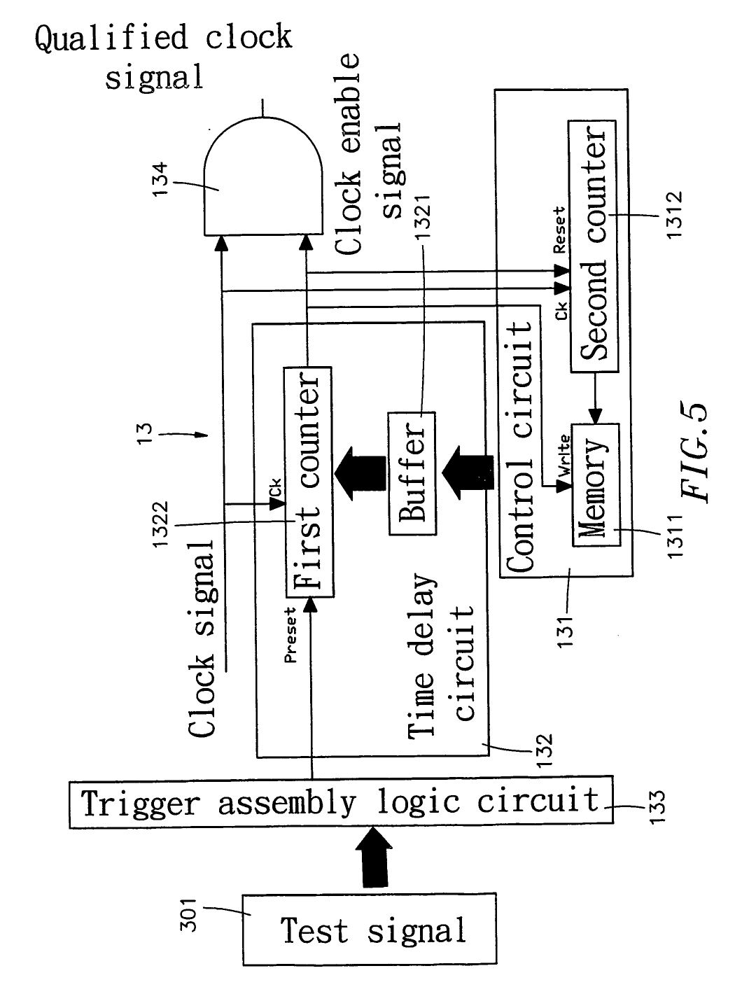

Referring to FIG. 5 and FIG. 4 again, when obtained a qualified clock, i.e., sampling clock, the user uses the control circuit 131 of the data retrieving circuit 13 to store a predetermined time delay default in the buffer 1321 of a delay circuit 132. When one or more test signals 301 entered, the user can use a trigger assembly logic circuit 133 to select edge trigger or level trigger for triggering, enabling the entered test signal 301 to output a clock qualifier signal to trigger preset. When preset triggered, the default value is transmitted from the buffer 1321 to a first counter 1322 causing the first counter 1322 to start counting. At this time, the output of clock enable is “Hi”. When the first counter 1322 counted up to the default value, the output of clock enable is changed from “Hi” to “Lo”, providing a complete clock enable, which comes with clock input through an AND gate 134 to provide a qualified clock, namely, the sampling clock, which is then transmitted to the control unit 11, enabling the control unit 11 to catch the complete waveform of the test sample 30. Therefore, the logic analyzer 10 receives a sampling clock input only during clock enable period, filtering unnecessary data.

Further, when a complete clock enable signal ended, the reset of a second counter 1312 of the control circuit 131 is triggered (zeroed), thereby causing the second counter 1312 to start counting up to the time when a next clock enable signal comes. Therefore, the value of the second counter 1312 is stored in a memory 1311 of the control circuit 131, and the value of the second counter 1312 been stored in the memory 1311 of the control circuit 131 is displayed on the display screen, enabling the user to know the time interval between the two clock enable signals.

Further, an OR gate may be used instead of the aforesaid AND gate 134.

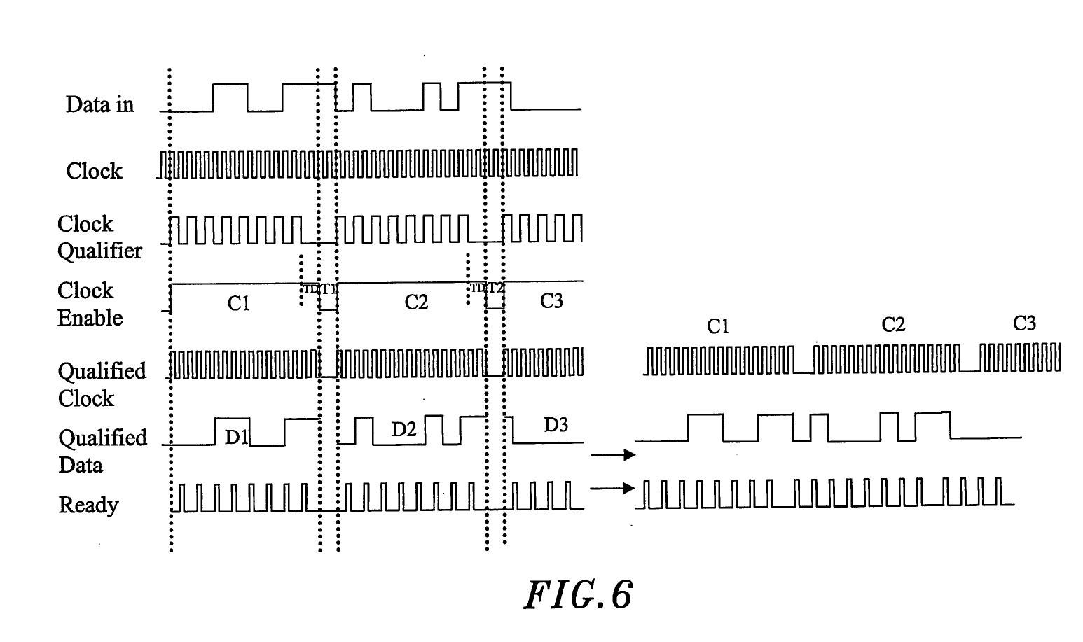

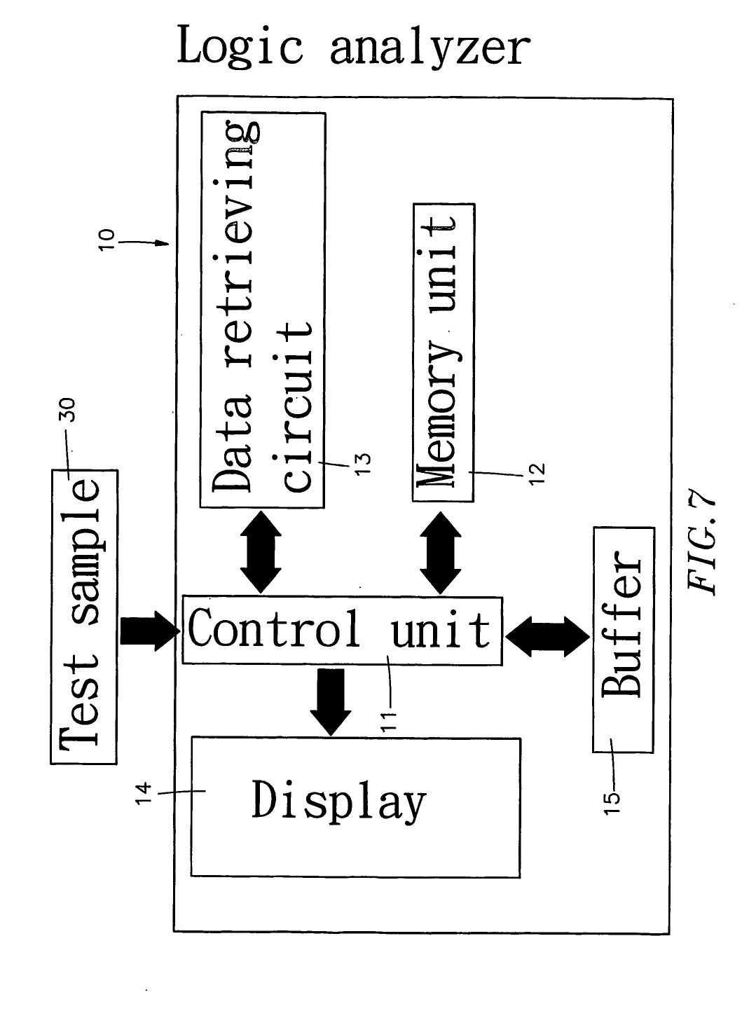

Referring to FIG. 6, when a series of clock qualifiers processed through the data retrieving circuit 13, a complete clock enable signal C1,C2,C3 is obtained. As illustrated, the qualified clock output is produced only when a clock enable signal available, and the important ready signal is retrieved when the qualified clock output produced. However, the appearance of TD (time delay) in the time enable signal represents the time delay set by the user. Due to the effect of TD, the series of clock qualifiers forms a complete clock enable signal. Further, T1 in the clock enable signal represents the time interval between two clock enables C1 and C2. FIG. 7 shows an alternate form of the present invention. According to this embodiment, the logic analyzer 10 comprises a control unit 11, a memory unit (for example, SRAM) 12, and a data retrieving circuit 13. When the data retrieving circuit 13 received a clock signal and a clock qualifier signal, it outputs a qualified clock to the control unit 11, causing the control unit 11 to catch test data from the test sample 30 subject to the sampling clock, i.e., the qualified clock. The control unit 11 further stores test data in the memory unit 12, and then writes storage test data from the memory unit 12 into a buffer 15, and then transfers test data from the buffer 15 to a display 14 of the logic analyzer 10 for review.

A prototype of logic analyzer data retrieving circuit and its retrieving method has been constructed with the features of the annexed drawings of FIGS. 4˜7. The logic analyzer data retrieving circuit and its retrieving method functions smoothly to provide all of the features discussed earlier.

Although particular embodiments of the invention have been described in detail for purposes of illustration, various modifications and enhancements may be made without departing from the spirit and scope of the invention. For example, the logic analyzer may be made having two or more data retrieving circuits. Accordingly, the invention is not to be limited except as by the appended claims.

1-18. (canceled)

19. A logic analyzer data retrieving method used in a logic analyzer comprising a control unit and a time delay circuit, wherein said control circuit comprises a memory and a second counter, and said time delay circuit comprises a first counter and a buffer, the method comprising the steps of:
providing and storing a time delay default value in said buffer of said time delay circuit;
presetting at least a clock qualifier signal based on a specific parameter;
triggering a preset of said first counter and transferring said default value from said buffer to said first counter to drive said first counter to start counting in response to said clock qualifier signal until said delay default value is reached;
capturing test data from a test sample electrically connected to the logic analyzer in response to said triggering of said preset of said first counter until said first counter counting reaches said delay default value, wherein said control unit is adopted for capturing said test data from a test sample; and
triggering a preset of said second counter, in response to said first counter counting reaching said delay default value, to start counting until the preset of the first counter is triggered again.

20. The logic analyzer data retrieving method as claimed in claim 19, wherein counting value of said second counter is stored in said memory unit when said second counter stops counting and then displaying the value on a display screen.

21. The logic analyzer data retrieving method as claimed in claim 19, further comprising a step of sampling clock input only during the period of a clock enable signal.

22. The logic analyzer data retrieving method as claimed in claim 21, wherein an output of said clock enable signal is low when said first counter starts counting, and the output of said clock enable signal is high when said first counter counted until said default value is reached.

23. A logic analyzer data retrieving method used in a logic analyzer comprising a control unit and a time delay circuit, wherein said control circuit comprises a memory and a second counter, and said time delay circuit comprises a first counter and a buffer, the method comprising the steps of:
providing and storing a time delay default value in said buffer of said time delay circuit;
presetting at least a clock qualifier signal based on a specific parameter;
triggering a preset of said first counter and transferring said default value from said buffer to said first counter to drive said first counter to start counting in response to said clock qualifier signal until said delay default value is reached;
capturing test data from a test sample electrically connected to the logic analyzer in response to said triggering of said preset of said first counter until said first counter counting reaches said delay default value, wherein said control unit is adopted for capturing said test data from a test sample; and
triggering a present of said second counter, in response to said first counter counting reaching said delay default value, to start counting until the preset of the first counter is triggered again, and wherein counting value of said second counter is stored in said memory unit when said second counter stops counting and then displaying the value on a display screen.

24. The logic analyzer data retrieving method as claimed in claim 23, further comprising a step of sampling clock input only during the period of a clock enable signal.

25. The logic analyzer data retrieving method as claimed in claim 24, wherein an output of said clock enable signal is low when said first counter starts counting, and the output of said clock enable signal is high when said first counter counted until said default value is reached.

26. A logic analyzer data retrieving circuit, comprising:
a control unit, comprising a memory and a second counter, adopted for capturing test data from a test sample electrically connected to the logic analyzer data retrieving circuit; and
a time delay circuit, comprising a first counter and a buffer, wherein said buffer is adopted for storing a time delay default value;
wherein at least a clock qualifier signal is preset in said logic analyzer data retrieving circuit based on a specific parameter,
wherein a preset of said first counter is triggered and said default value is transferred from said buffer to said first counter to drive said first counter to start counting in response to said clock qualifier signal until said delay default value is reached and test data from said test sample is continuously captured until said first counter counting reaches said delay default value, and
wherein a preset of said second counter is triggered when said first counter counting reaches said delay default value and starts counting until the present of the first counter is triggered again.

27. The logic analyzer data retrieving circuit as claimed in claim 26, wherein counting value of said second counter is stored in said memory unit when said second counter stops counting and then displaying the value on a display screen.

28. The logic analyzer data retrieving circuit as claimed in claim 26, further comprising a trigger assembly logic circuit capable of receiving multiple test signals from multiple test samples.

29. A logic analyzer data retrieving circuit comprising:
a control unit, comprising a memory and a second counter, adopted for capturing test data from a test sample electrically connected to the logic analyzer data retrieving circuit; and
a time delay circuit, comprising a first counter and a buffer, wherein said buffer is adopted for storing a time delay default value;
wherein at least a clock qualifier signal is preset in said logic analyzer data retrieving circuit based on a specific parameter,
wherein a preset of said first counter is triggered and said default value is transferred from said buffer to said first counter to drive said first counter to start counting in response to said clock qualifier signal until said delay default value is reached and test data from said test sample is continuously captured until said first counter counting teaches said delay default value,
wherein a preset of said second counter is triggered when said first counter counting reaches said delay default value and starts counting until the preset of the first counter is triggered again, and
wherein counting value of aid second counter is stored in said memory unit when said second counter stops counting and then displaying the value on a display screen.

30. The logic analyzer data retrieving circuit as claimed in claim 29, wherein counting value of said second counter is stored in said memory unit when said second counter stops counting and then displaying the value on a display screen.

31. The logic analyzer data retrieving circuit as claimed in claim 29, further comprising a trigger assembly logic circuit capable of receiving multiple test signals from multiple test samples.
